(19) United States
(12) Patent Application Publication
(10) Pub. No.: US 2008/0150144 A1
(43) Pub. Date: Jun. 26, 2008

(54) GUARD RING IN SEMICONDUCTOR DEVICE AND FABRICATING METHOD THEREOF

(76) Inventor: Won-Hyo Park, Gyeonggi-do (KR)

Correspondence Address: SHERR & NOURSE, PLLC, 620 HERNDON PARKWAY, SUITE 200, HERNDON, VA, 20170, US

(21) Appl. No.: 11/937,912

(22) Filed: Nov. 9, 2007

(30) Foreign Application Priority Data
Dec. 5, 2006 (KR) 10-2006-0122137

(51) Int. Cl. H01L 23/52; H01L 21/4763

(52) U.S. Cl. 257/758; 438/637; 257/E23.141; 257/E21.495

(57) ABSTRACT

A guard ring in a semiconductor device can include a plurality of first latticed metal plugs formed over a semiconductor substrate; a plurality of first latticed metal layer patterns formed over the plurality of first latticed metal plugs; a plurality of second latticed metal plugs formed over the plurality of first latticed metal layer patterns; a plurality of second latticed metal layer patterns formed over the plurality of second latticed metal plugs; a plurality of third latticed metal plugs formed over the plurality of second latticed metal layer patterns; a plurality of third latticed metal layer patterns formed over the plurality of third latticed metal plugs; and a protective layer formed over the semiconductor substrate including the plurality of third latticed metal layer patterns.

The present application claims priority under 35 U.S.C. 119 to Korean Patent Application No. 10-2006-0122137, (filed on Dec. 5, 2006), which is hereby incorporated by reference in its entirety.

### BACKGROUND

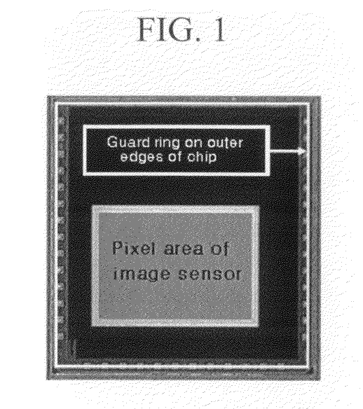

As illustrated in example FIG. 1, after completion of a final process for fabricating a semiconductor device, a semiconductor guard ring may be provided to outer edges of the semiconductor device to protect the inner circuits of the semiconductor device from moisture or contamination generated during fabrication and the environment.

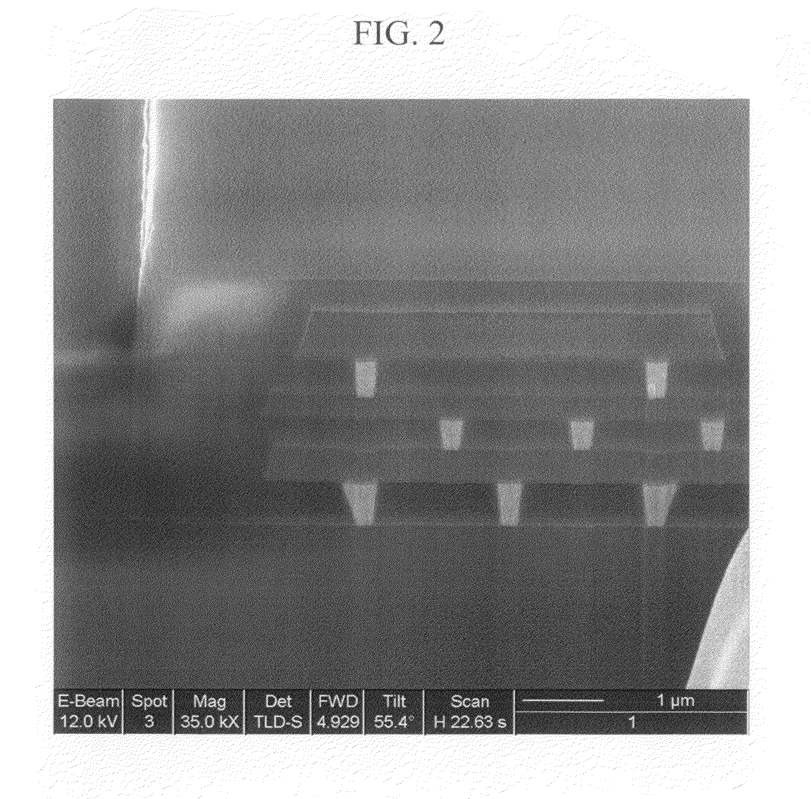

As illustrated in example FIG. 2, a semiconductor device guard ring has a configuration formed by sequentially forming a first metal plug, a first metal line, a second metal plug, a second metal line, a third metal plug and a third metal line on and/or over an uppermost surface of a semiconductor substrate and then forming a protective layer thereon.

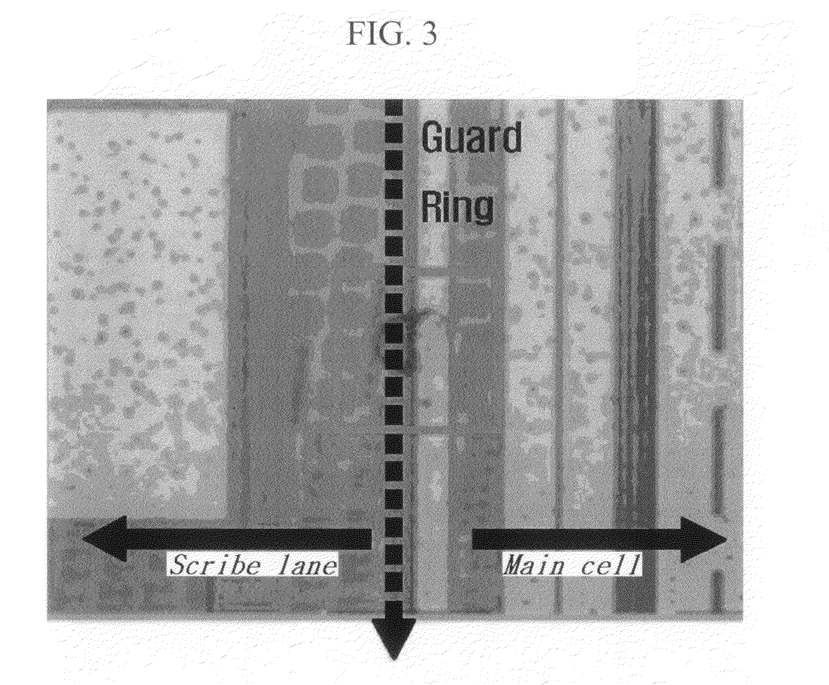

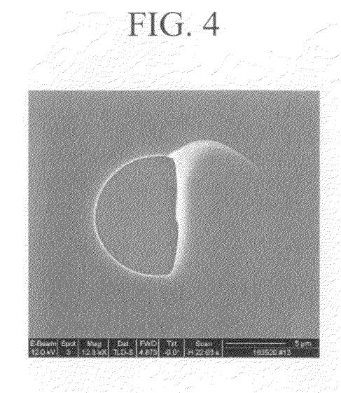

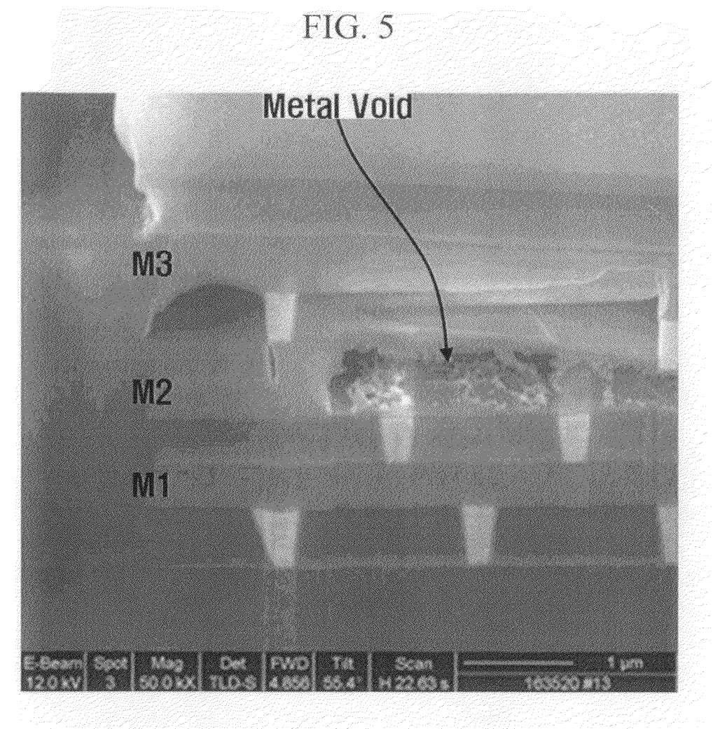

As illustrated in example FIGS. 3 to 5, when performing annealing after completion of the semiconductor device fabrication, circle defects may be generated due to thermal stresses in metal plugs, insulating layers and metal lines and/or metal voids.

### SUMMARY

Embodiments relate to a guard ring of a semiconductor device that can be suitable for preventing the generation of thermal stresses after completion of semiconductor device fabrication.

Embodiments relate to a method of fabricating a semiconductor device guard ring that can include at least one of the following steps: forming a plurality of first latticed metal plugs over a semiconductor substrate and a plurality of first latticed metal layer patterns over the plurality of first latticed metal plugs; forming a plurality of second latticed metal plugs over the plurality of first latticed metal layer patterns and a plurality of second latticed metal layer patterns over the plurality of second latticed metal plugs; forming a plurality of third latticed metal plugs over the plurality of second latticed metal layer patterns and a plurality of third latticed metal layer patterns over the plurality of third latticed metal plugs; and then forming a protective layer over the plurality of third latticed metal layer patterns.

Embodiments relate to a semiconductor device guard ring that can include: a plurality of first latticed metal plugs formed over a semiconductor substrate; a plurality of first latticed metal layer patterns formed over the plurality of first latticed metal plugs; a plurality of second latticed metal plugs formed over the plurality of first latticed metal layer patterns; a plurality of second latticed metal layer patterns formed over the plurality of second latticed metal plugs; a plurality of third latticed metal plugs formed over the plurality of second latticed metal layer patterns; a plurality of third latticed metal layer patterns formed over the plurality of third latticed metal plugs; and a protective layer formed over the semiconductor substrate including the plurality of third latticed metal layer patterns.

Embodiments relate to a semiconductor device guard ring that can include: a first insulating layer formed over a semiconductor substrate; a plurality of first latticed metal plugs formed in the first insulating layer; a second insulating layer formed over the semiconductor substrate including the first insulating layer and the plurality of first latticed plugs; a plurality of first latticed metal layer patterns formed in the second insulating layer; a third insulating layer formed over the semiconductor substrate including the second insulating layer and the plurality of first latticed metal layer patterns; a plurality of second latticed metal plugs formed in the third insulating layer; a fourth insulating layer formed over the semiconductor substrate including the third insulating layer and the plurality of second latticed metal plugs; a plurality of second latticed metal layer patterns formed in the fourth insulating layer; a fifth insulating layer formed over the semiconductor substrate including the fourth insulating layer and the plurality of second latticed metal layer patterns; a plurality of third latticed metal plugs formed in the fifth insulating layer; a sixth insulating layer formed over the semiconductor substrate including the fifth insulating layer and the plurality of third latticed metal plugs; a plurality of third latticed metal layer patterns formed in the fifth insulating layer; and a protective layer formed over the semiconductor substrate including the fifth insulating layer and the plurality of third latticed metal layer patterns.

### DRAWINGS

Example FIGS. 1 to 5 illustrate a semiconductor device guard ring provided to outer edges of a semiconductor device.

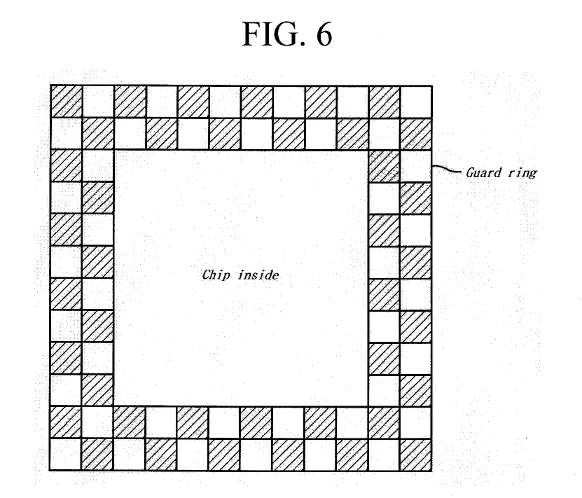

Example FIG. 6 illustrates a semiconductor device guard ring provided to outer edges of a semiconductor device, in accordance with embodiments.

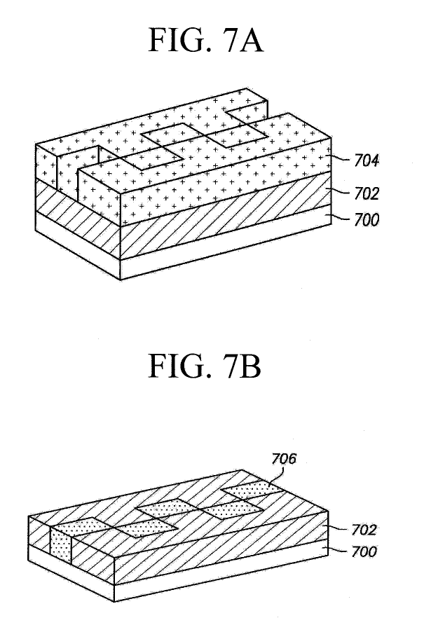

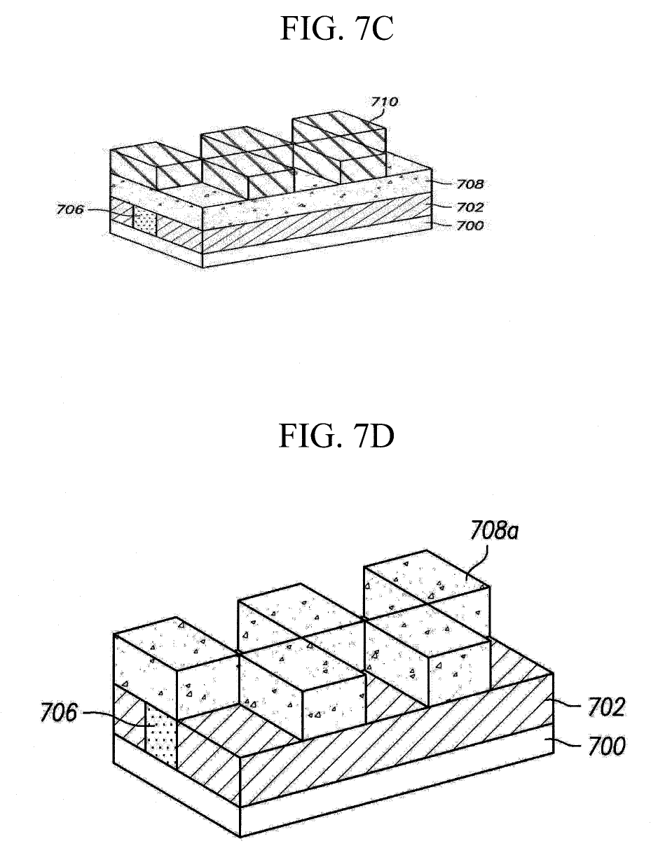

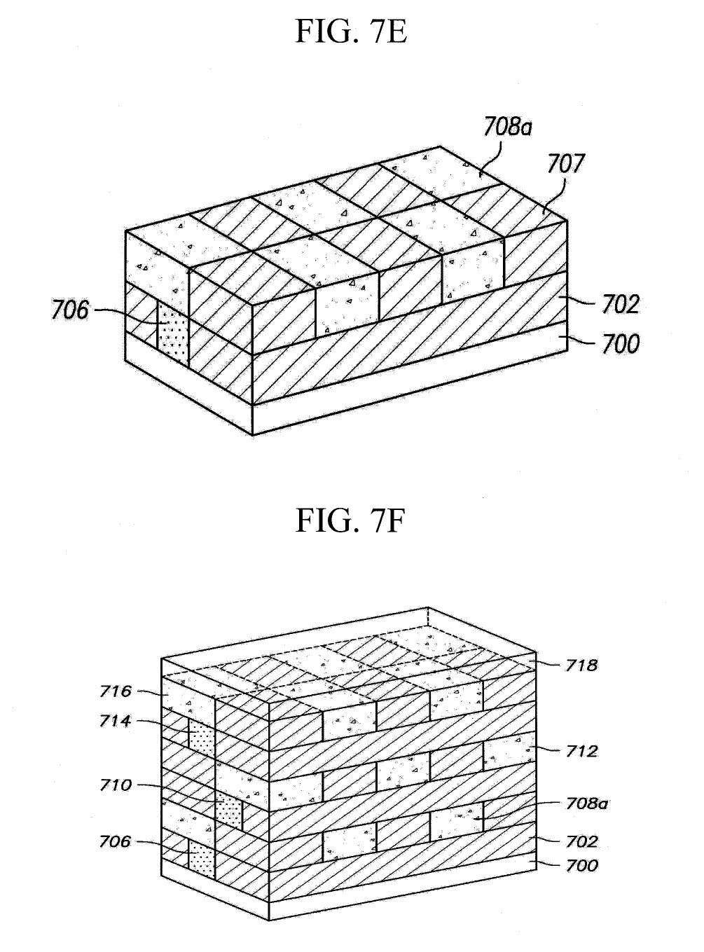

Example FIGS. 7A to 7F illustrate a method of forming a semiconductor device guard ring, in accordance with embodiments.

### DESCRIPTION

As illustrated in example FIG. 6, a semiconductor device guard ring can be provided at the outer edges of the semiconductor device and can have a lattice structure including a metal plug and layer pattern.

As illustrated in example FIG. 7, first insulating layer 702 can be deposited on and/or over semiconductor substrate 700. To form a via hole, a photoresist can be coated on and/or over first insulating layer 702 and subsequently patterned to form first latticed photoresist pattern 704.

As illustrated in example FIG. 7B, a via hole in a lattice arrangement can be formed by performing an etch process using first latticed photoresist pattern 704 as an etch mask. Subsequently, ashing and cleaning processes can be performed to remove first latticed photoresist pattern 704.

Subsequently, a first metal layer composed of a metal material such as tungsten and the like can be deposited using chemical vapor deposition (CVD) on and/or over semiconductor substrate 700 including the latticed via hole. The first metal layer can then be planarized by an etchback or CMP (chemical mechanical polishing) process to form a plurality of first latticed metal plugs 706.

As illustrated in example FIG. 7C, second metal layer 708 can be formed on and/or over semiconductor substrate 700 including first latticed metal plugs 706. Second metal layer 708 can be composed of metal material such as Al, Al—Cu alloy and the like. Subsequently, a photoresist can be coated on and/or over second metal layer 708 and then patterned to form second latticed photoresist pattern 710.

As illustrated in example FIG. 7D, a plurality of first latticed metal layer patterns 708a can be formed by performing an etching process using second latticed photoresist pattern 710 as an etch mask. Ashing and cleaning can then be carried out to remove second latticed photoresist pattern 710. First latticed metal layer patterns 708a can be configured as a plurality of cubic lattices each of which has a size of approximately 3 μm×3 μm.

As illustrated in example FIG. 7E, second insulating layer 707 can be deposited on and/or over semiconductor substrate 700 including first latticed metal layer patterns 708a and then planarized using an etchback or CMP process.

As illustrated in example FIG. 7F, the previous steps of forming first latticed metal plugs 706 and first metal layer patterns 708a can be repeated to form a plurality of second latticed metal plugs 710, a plurality of second latticed metal layer patterns 712, a plurality of third latticed metal plugs 714, and a plurality of third latticed metal layer patterns 716. Subsequently, a protective layer 718 can be formed on and/or over semiconductor substrate 700 including third latticed metal layer patterns 716. Protective layer 718 can be formed by depositing an oxide material such as of USG (undoped silicate glass) using CVD.

In particular, the semiconductor device guard ring can be configured to have first latticed metal plugs 706, first latticed metal layer patterns 708a, second latticed metal plugs 710, second latticed metal layer patterns 712, third latticed metal plugs 714, and third latticed metal layer patterns 716.

Latticed metal plugs 706, 710 and 714 and latticed metal payer patterns 708a, 712 and 716 can be formed to increase surface areas of the metal plug, the metal layer pattern and the insulating layer to thereby enhance the rate of thermal radiation. Accordingly, the semiconductor substrate guard ring can reduce the thermal stress at a critical point, whereby a circle defect or metal void can be prevented from the thermal stress after completion of a semiconductor device fabricating process.

Circle defects or metal voids caused by thermal stresses of metal plug, insulating layer and metal line in the course of annealing after the semiconductor device fabrication can also be avoided by forming a plurality of metal plugs and metal layer patterns in a lattice arrangement.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a plurality of first latticed metal plugs over a semiconductor substrate and a plurality of first latticed metal layer patterns over the plurality of first latticed metal plugs;
forming a plurality of second latticed metal plugs over the plurality of first latticed metal layer patterns and a plurality of second latticed metal layer patterns over the plurality of second latticed metal plugs;
forming a plurality of third latticed metal plugs over the plurality of second latticed metal layer patterns and a plurality of third latticed metal layer patterns over the plurality of third latticed metal plugs; and then
forming a protective layer over the plurality of third latticed metal layer patterns.

2. The method of claim 1, forming the plurality of first latticed metal layer patterns comprises:
forming a first insulating layer over the semiconductor substrate and a plurality of first latticed photoresist patterns over the first insulating layer;
forming a latticed via hole by etch using the first latticed photoresist pattern as an etch mask;
forming a first metal layer on the semiconductor substrate including the latticed via hole after removing the first latticed photoresist pattern;
forming the first latticed metal plug by planarizing the first metal layer;
forming a second metal layer on the semiconductor substrate including the first latticed metal plug;
forming a second latticed photoresist pattern on the second metal layer;
forming the first latticed metal layer pattern by etching using the plurality of second latticed photoresist patterns as etch masks;
forming a second insulating layer over the semiconductor substrate including the plurality of first latticed metal layer patterns after removing the plurality of second latticed photoresist patterns; and then
planarizing the second insulating layer and the plurality of first latticed metal layer patterns.

3. The method of claim 2, wherein the first metal layer is formed of tungsten by chemical vapor deposition (CVD).

4. The method of claim 2, wherein the second metal layer is formed of either Al or Al—Cu alloy by physical vapor deposition (PVE-DEP).

5. The method of claim 1, the second latticed metal layer pattern forming step comprising the steps of:
forming a third insulating layer on the semiconductor substrate including the first latticed metal layer pattern and a third latticed photoresist pattern on the third insulating layer;
forming a latticed via hole by etching using the third latticed photoresist pattern as an etch mask;
forming a third metal layer on the semiconductor substrate including the latticed via hole after removing the third latticed photoresist pattern;
forming the second latticed metal plug by planarizing the third metal layer;
forming a fourth metal layer on the semiconductor substrate including the second latticed metal plug;
forming a fourth latticed photoresist pattern on the fourth metal layer;
forming the second latticed metal layer pattern by etch using the fourth latticed photoresist pattern as an etch mask;
forming a fourth insulating layer on the semiconductor substrate including the second latticed metal layer pattern after removing the fourth latticed photoresist pattern; and
planarizing the fourth insulating layer and the second latticed metal layer pattern.

6. The method of claim 5, wherein the third metal layer comprises a tungsten material and is formed by chemical vapor deposition.

7. The method of claim 5, wherein the fourth metal layer comprises at least one of an Al material and an Al—Cu alloy material and is formed by physical vapor deposition.

8. The method of claim 1, wherein forming the plurality of third latticed metal layer patterns comprises:
forming a fifth insulating layer over the semiconductor substrate including the plurality of second latticed metal layer patterns and a plurality of fifth latticed photoresist patterns over the fifth insulating layer;
forming a latticed via hole by etching using the plurality of fifth latticed photoresist patterns as etching masks;
forming a fifth metal layer over the semiconductor substrate including the latticed via hole after removing the plurality of fifth latticed photoresist patterns;
forming the plurality of third latticed metal plugs by planarizing the fifth metal layer;
forming a sixth metal layer over the semiconductor substrate including the plurality of third latticed metal plugs;
forming a plurality of sixth latticed photoresist patterns over the sixth metal layer;
forming the plurality of third latticed metal layer patterns by etching using the plurality of sixth latticed photoresist patterns as etching masks;
forming a sixth insulating layer over the semiconductor substrate including the plurality of third latticed metal layer patterns after removing the plurality of sixth latticed photoresist patterns; and then
planarizing the sixth insulating layer and the plurality of third latticed metal layer patterns.

9. The method of claim 8, wherein the fifth metal layer comprises a tungsten material and is formed by chemical vapor deposition.

10. The method of claim 9, wherein the sixth metal layer comprises at least one of an Al material and an Al—Cu alloy material and is formed by physical vapor deposition.

11. The method of claim 1, wherein each of the first latticed metal layer patterns, the second latticed metal layer patterns and the third latticed metal layer patterns are each configured as 3 μm×3 μm cubic lattices.

12. The method of claim 1, wherein the protective layer comprises an oxide material and is formed by chemical vapor deposition.

13. The method of claim 12, wherein the oxide material comprises undoped silicate glass.

14. An apparatus comprising:
a plurality of first latticed metal plugs formed over a semiconductor substrate;
a plurality of first latticed metal layer patterns formed over the plurality of first latticed metal plugs;
a plurality of second latticed metal plugs formed over the plurality of first latticed metal layer patterns;
a plurality of second latticed metal layer patterns formed over the plurality of second latticed metal plugs;
a plurality of third latticed metal plugs formed over the plurality of second latticed metal layer patterns;
a plurality of third latticed metal layer patterns formed over the plurality of third latticed metal plugs; and
a protective layer formed over the semiconductor substrate including the plurality of third latticed metal layer patterns.

15. The apparatus of claim 14, wherein the first latticed metal plugs, the second latticed metal plugs and the third latticed metal plugs each comprise a tungsten material.

16. The apparatus of claim 14, wherein the first latticed metal layer patterns, the second latticed metal layer patterns and the third latticed metal layer patterns each comprise at least one of an Al material and an Al—Cu alloy material.

17. The apparatus of claim 14, wherein the first latticed metal layer patterns, the second latticed metal layer patterns and the third latticed metal layer patterns are each configured as 3 μm×3 μm cubic lattices.

18. The apparatus of claim 14, wherein the protective layer comprises an oxide material.

19. The apparatus of claim 14, wherein the oxide material comprises undoped silicate glass.

20. An apparatus comprising:
a first insulating layer formed over a semiconductor substrate;
a plurality of first latticed metal plugs formed in the first insulating layer;
a second insulating layer formed over the semiconductor substrate including the first insulating layer and the plurality of first latticed plugs;
a plurality of first latticed metal layer patterns formed in the second insulating layer;
a third insulating layer formed over the semiconductor substrate including the second insulating layer and the plurality of first latticed metal layer patterns;
a plurality of second latticed metal plugs formed in the third insulating layer;
a fourth insulating layer formed over the semiconductor substrate including the third insulating layer and the plurality of second latticed metal plugs;
a plurality of second latticed metal layer patterns formed in the fourth insulating layer;
a fifth insulating layer formed over the semiconductor substrate including the fourth insulating layer and the plurality of second latticed metal layer patterns;
a plurality of third latticed metal plugs formed in the fifth insulating layer;
a sixth insulating layer formed over the semiconductor substrate including the fifth insulating layer and the plurality of third latticed metal plugs;
a plurality of third latticed metal layer patterns formed in the fifth insulating layer; and
a protective layer formed over the semiconductor substrate including the fifth insulating layer and the plurality of third latticed metal layer patterns.
